(19) United States
(12) Patent Application Publication
(10) Pub. No.: US 2016/0223590 A1
(43) Pub. Date: Aug. 4, 2016

(54) PROBE HEAD AND UPPER GUIDER PLATE

(71) Applicant: MPI CORPORATION, Chu-Pei City (TW)

(72) Inventors: Chih-Hao HSU, Chu-Pei City (TW); Sang-Yi LIN, Chu-Pei City (TW); Yung-Hsin CHEN, Chu-Pei City (TW)

(21) Appl. No.: 15/012,093

(22) Filed: Feb. 1, 2016

(30) Foreign Application Priority Data
Feb. 4, 2015 (TW) 104103716

(51) Int. Cl. G01R 1/073; G01R 31/28

(52) U.S. Cl. CPC G01R 1/07357; G01R 31/2889; G01R 1/07342

(57) ABSTRACT

A probe head for a vertical probe card includes an upper guider plate, a lower guider plate and a plurality of probes. The upper guider plate has a plurality of upper through holes. The lower guider plate is located by one side of the upper guider plate and has a plurality of lower through holes. Each of the probes is positioned through one of the upper through holes of the upper guider plate and one of the lower through holes of the lower guider plate. The upper guider plate has a light transmittance of at least 75%, and is made of a material having a Moh's hardness of at least 5.

### BACKGROUND OF THE INVENTION

1. Field of the Invention The present invention relates generally to a probe head and an upper guider plate, and more particularly to a probe head and an upper guider plate, which are adapted for being used in a vertical probe card.

2. Description of the Related Art

Semiconductor integrated circuit chips are usually tested in electrical properties by means of a probe card. The vertical probe card usually includes a printed circuit board, a space transformer and a probe head, wherein the probe head is adapted for electrically connecting a circuit board with a device under test (hereinafter referred to as “DUT”), so that the DUT can be tested in the electrical properties. Specifically speaking, the probe head at least includes an upper guider plate, a lower guider plate, and a plurality of probes. Each of the upper guider plate and the lower guider plate of the probe head usually has a plurality of through holes. In the assembling process of the probe head, each of the probes has to be inserted through associated through holes of the upper and lower guider plates, so that the upper and lower guider plates are aligned and coupled with each other. The aforesaid assembling process should be carefully carried out to prevent the probes from damage.

However, if the to-be-tested contacts of the DUT have small pitches therebetween, the corresponding probes of the probe head should also have small pitches therebetween, so as to conform to the requirement of fine pitch. In such condition, it is relatively more difficult to align and couple the upper and lower guider plates with each other. For example, under the requirement of conforming to fine pitch, the probes are very thin and the through holes of the upper guider plate are very small; in addition, under the condition that the upper guider plate is opaque, the positions of the tails of the probes can not be observed directly and precisely because the through holes of the upper guider plate are too small to be passed through by light. Therefore, the relative positions between the tails of the probes and the through holes of the opaque upper guider plate can only be observed roughly, but not precisely. As a result, the probes are liable to be damaged in the assembling process of the probe head, and the efficiency of assembling the probe head is lowered. Therefore, how to solve the aforesaid problems is an important task for the related field.

### SUMMARY OF THE INVENTION

It is an objective of the present invention to provide a probe head which is adapted for a vertical probe card for testing the DUT with the contacts conforming to fine pitch. Besides, the probe head is easily assembled, so the probes thereof are less possibly damaged.

It is another objective of the present invention to provide an upper guider plate which is adapted for a probe head of a vertical probe card, and facilitates the assembly of the probe head which is adapted for testing the DUT with the contacts conforming to fine pitch, so that the probes of the probe head are less possibly damaged.

To attain the above objectives, the present invention provides a probe head which is adapted for a vertical probe card, and includes an upper guider plate, a lower guider plate, and a plurality of probes. The upper guider plate has a plurality of upper through holes. The lower guider plate is located by one side of the upper guider plate and has a plurality of lower through holes. Each of the probes is positioned through one of the upper through holes of the upper guider plate and one of the lower through holes of the lower guider plate. The upper guider plate has a light transmittance of at least 75%, and is made of a material having a Moh's hardness of at least 5.

To attain the above objectives, the present invention provides an upper guider plate which is adapted for a probe head of a vertical probe card, has a plurality of upper through holes and a light transmittance of at least 75%, and is made of a material having a Moh's hardness of at least 5.

As a result, in the probe head of the present invention, the upper guider plate with the light transmittance of at least 75% enables the precise positions of the tails of the probes to be observed directly, so the tails of the probes can be easily inserted through the upper through holes of the upper guider plate. Besides, even though the probe head conforms to the requirement of fine pitch, the probes thereof are still less possibly damaged in the installation process and the efficiency of assembling the probe head can be improved.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic perspective view showing the structure of a probe head according to an embodiment of the present invention;

FIG. 2A is a schematic perspective view of a lower guider plate and a positioning member as shown in FIG. 1;

FIG. 2B is a top view of the lower guider plate and the positioning member as shown in FIG. 1;

FIG. 2C is a schematic perspective view of a probe as shown in FIG. 1;

FIG. 3 is similar to FIG. 2B, but further showing that the probes shown in FIG. 2C are inserted in positioning through holes of the positioning member;

FIG. 4A is a schematic view showing that the probes shown in FIG. 2C are about to be inserted through a conventional upper guider plate;

FIG. 4B is a schematic view showing that the probes shown in FIG. 2C are about to be inserted through the upper guider plate shown in FIG. 1; and

FIG. 5 is a lateral sectional view of a probe head according to another embodiment of the present invention.

### DETAILED DESCRIPTION OF THE INVENTION

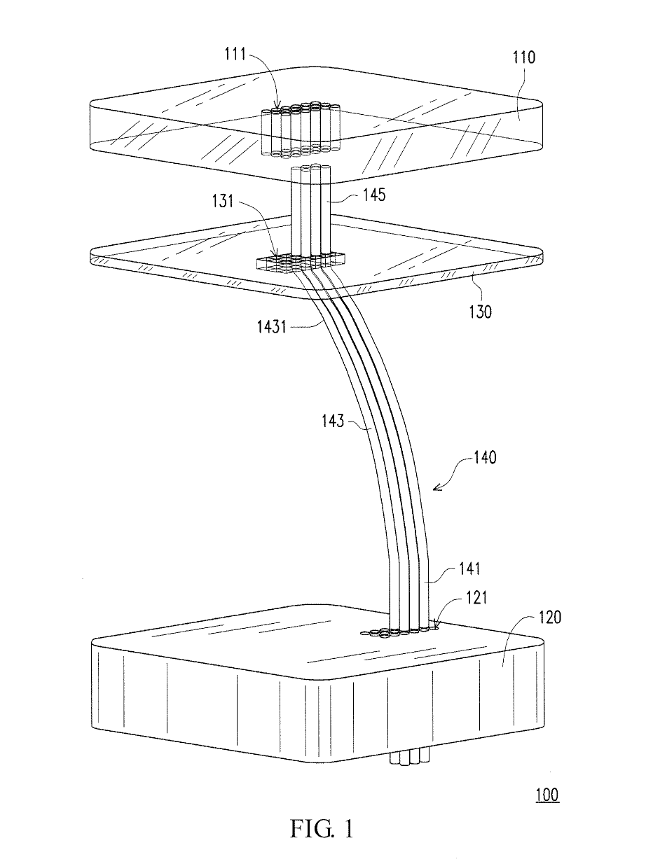

FIG. 1 is a schematic perspective view showing the structure of a probe head according to an embodiment of the present invention. Referring to FIG. 1, the probe head 100 in this embodiment is adapted for being used in a vertical probe card. Specifically speaking, the probe head 100 as shown in FIG. 1 includes an upper guider plate 110, a lower guider plate 120, at least one positioning member 130, and a plurality of probes 140. It should be noticed here that the probe head of the present invention applied to a vertical probe card is adapted for testing the DUT with the contacts conforming to fine pitch, which means the pitches between the contacts are smaller than 400 micrometers (μm).

In detail, the upper guider plate 110 in this embodiment has a light transmittance of at least 75%, and is made of a material having a Moh's hardness of at least 5. Specifically speaking, the upper guider plate 110 in this embodiment may, but not limited to, be made of a glass substrate or a sapphire substrate. Besides, the thickness of the upper guider plate 110 in this embodiment is at most 800 micrometers and preferably ranges from 200 micrometers to 800 micrometers. Because the probes 140 conforming to the requirement of fine pitch are very thin, the thinner the upper guider plate 110 is, the lower risk of damaging the probes 140 is taken when the very thin probes 140 are inserted through the very small upper through holes 111 of the upper guider plate 110.

Furthermore, because the upper guider plate 110 is made of the material having the Moh's hardness of at least 5, the surface of the upper guider plate 110 is uneasily damaged by the probes 140, so that the upper guider plate 110 can maintain the light transmittance to a certain extent. Besides, the upper guider plate 110 may be made of the glass substrate or the sapphire substrate, thereby uneasily bent and quite flat. Therefore, the upper guider plate 110 is less possible to have the problem of deformation which causes difficulty in installation of the probes. In other words, if the upper guider plate is made of acrylic, it is not hard enough, thereby probably not flat enough. Besides, the acrylic upper guider plate usually has the thickness of at least 1000 micrometers; therefore, the hardness and the thickness of the acrylic upper guider plate are both unable to satisfy the present testing condition, thereby unsuitable to serve as the upper guider plate of the present invention.

As shown in FIG. 1, in this embodiment the upper guider plate 110 has a plurality of upper through holes 111, and the lower guider plate 120 has a plurality of lower through holes 121. Besides, in this embodiment a pitch of less than 400 micrometers is provided between two adjacent upper through holes 111. Preferably, the aforesaid pitch may range from 40 micrometers to 400 micrometers. Of course the aforesaid pitch provided between two adjacent upper through holes 111 may, but not limited to, range from 40 micrometers to 200 micrometers, so that the probe head 100 applied to the vertical probe card can conform to the requirement of fine pitch. It should be noticed that the two adjacent upper through holes 111 mentioned here refers to any two adjacent upper through holes, which means the upper guider plate may have only one pair of upper through holes 111 adjacent to each other and answering to the aforesaid limitation in the pitch therebetween.

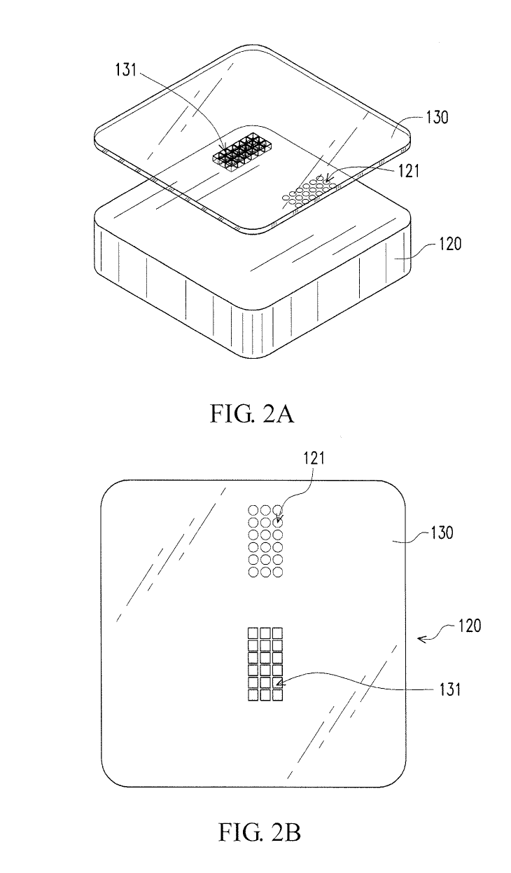

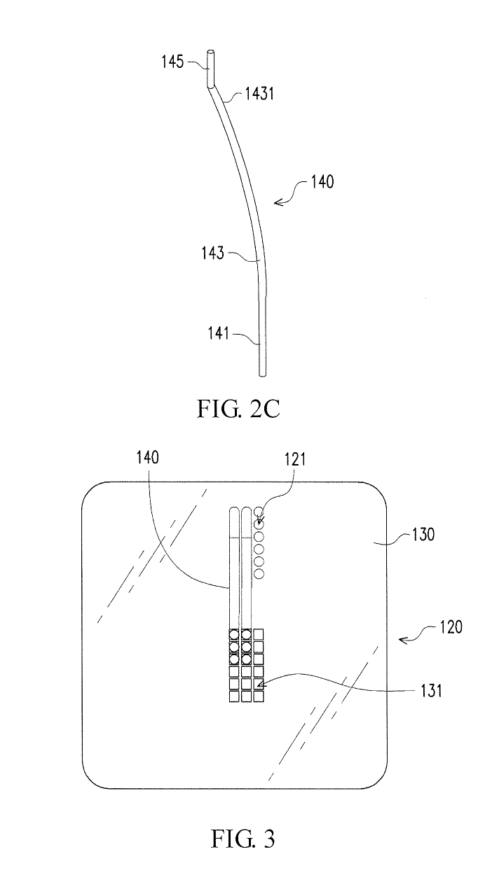

As shown in FIG. 1, in this embodiment the lower guider plate 120 is located by one side of the upper guider plate 110, i.e. located beneath the upper guider plate 110, and the positioning member 130 is disposed between the upper guider plate 110 and the lower guider plate 120. Specifically speaking, the positioning member 130 in this embodiment assists each of the probes 140 in being positioned through one of the upper through holes 111 of the upper guider plate 110 and one of the lower through holes 121 of the lower guider plate 120. Detailed description will be given hereunder by reference to FIGS. 2A-4B.

FIG. 2A is a schematic perspective view of the lower guider plate and the positioning member as shown in FIG. 1. FIG. 2B is a top view of the lower guider plate and the positioning member as shown in FIG. 1. FIG. 2C is a schematic perspective view of the probe as shown in FIG. 1. Referring to FIG. 2A and 2B, the positioning member 130 in this embodiment has a light transmittance of at least 75%, and is made of a material having a Moh's hardness of at least 5. Specifically speaking, the positioning member 130 may, but not limited to, be made of a glass substrate or a sapphire substrate. On the other hand, as shown in FIG. 2C, the probes 140 in this embodiment may be made of metal and configured with elasticity. The probes 140 are the so-called formed probes, which are made of wires by mechanical pressing process. The probes 140 in this embodiment are cobra probes, which belong to a kind of formed probe. Each of the probes 140 is provided in order with a pinpoint 141, a body 143 and a tail 145, wherein the tail 145 has substantially circular cross sections and the body 143 has substantially elliptic or rectangular cross sections. The body 143 of the probe 140 has an elastic portion 1431 serving as a buckling structure, so the probe 140 will be buckled by an external force and generate an elastic force resulted from deformation. In other embodiments, the probes may be the so-called MEMS (Microelectromechanical Systems) probes, which are made by the MEMS manufacturing process, and may be MEMS straight probes, MEMS cobra probes or MEMS pogo probes. In other embodiments, the probes may be pogo probes made of wires by mechanical pressing process. In other embodiments, the probes may be vertical straight probes made of enameled wires. The type of the probes is not a limitation in the present invention.

FIG. 3 is similar to FIG. 2B, but further showing that probes shown in FIG. 2C are inserted in positioning through holes of the positioning member. Referring to FIGS. 2A, 2B and 3, the positioning member 130 has a plurality of positioning through holes 131 for assisting positioning of the probes 140. Specifically speaking, the aforesaid probe head 100 in this embodiment may be assembled by the following process. At first, the positioning member 130 is disposed on the lower guider plate 120, and the pinpoints 141 of the probes 140 are inserted into the positioning through holes 131 and the lower through holes 121. Then, the positioning member 130 is pulled up to the direction opposite to the lower guider plate 130 to pass by the bodies 143 of the probes 140 and let the tails 145 of the probes 140 be positioned through the positioning through holes 131. It should be noted that the aforesaid process of installing the probes is not the limitation in the present invention. In this embodiment, because the positioning member 130 has the light transmittance of at least 75%, the relative positions between the pinpoints 141 of the probes 140 and the lower through holes 121 of the lower guider plate 120 can be clearly observed while the pinpoints 141 of the probes 140 are inserted through the positioning through holes 131 of the positioning member 130 and about to be inserted through the lower through holes 121 of the lower guider plate 120, so that the probes 140 can be adjusted in the positions thereof, thereby installed more quickly. Besides, the positioning member 130 may be made of a glass substrate or a sapphire substrate having the Moh's hardness of at least 5, thereby uneasily bent and quite flat. Therefore, the positioning member 130 is less possible to have the problem of deformation which may cause separation of the probe 140 from the positioning member 130. That means the probes 140 are less possibly separated from the positioning member 130 in the aforesaid process that the positioning member 130 is pulled up toward the direction opposite to the lower guider plate 120 to pass by the bodies 143 of the probes 140 and let the tails 145 of the probes 140 be positioned through the positioning through holes 131. In other words, if the positioning member is made of a translucent or flexible material such as a film, it may have the problems of light reflection or insufficient flatness, thereby unable to satisfy the present testing condition and unsuitable to serve as the positioning member of the present invention.

As a result, the pinpoints 141 of the probes 140 are easily inserted through the positioning through holes 131 of the positioning member 130 and the lower through holes 121 of the lower guider plate 120, and the positioning through holes 131 can limit the positions of the probes 140. It should be noticed that this embodiment takes the probe head having one positioning member 130 as an instance, but the amount of the positioning member 130 is not limited. In other embodiments, the probe head may have a plurality of positioning members piled on one another; in such condition, the positioning through holes of the positioning members are not limited to be shaped to conform with the body of the probe. For example, if the probe head has two positioning members, namely first and second positioning members, each first positioning through hole of the first positioning member may be configured to accommodate at least two probes, and each second positioning through hole of the second positioning member may be configured to accommodate only one probe. In the assembling process of such probe head, the probes can be roughly positioned at first by the first positioning member in a way that each first positioning through holes is passed through by two probes; after that, the probes can be further positioned by the second positioning member in a way that the two probes in the same first positioning through hole are separated or staggered by two second positioning through holes, each of which can be passed through by only one probe. Therefore, using a plurality of positioning members can also make the probes 140 easily installed, limit the positions of the probes 140, and achieve the aforesaid effects and advantages that will not be repeatedly mentioned hereunder. It should be noticed that the aforesaid upper through holes 111 and lower through holes 121 may, but not limited to, be substantially shaped as circles or rectangles; the positioning through holes 131 may, but not limited to, be substantially shaped as ellipses, rectangles or non-circles.

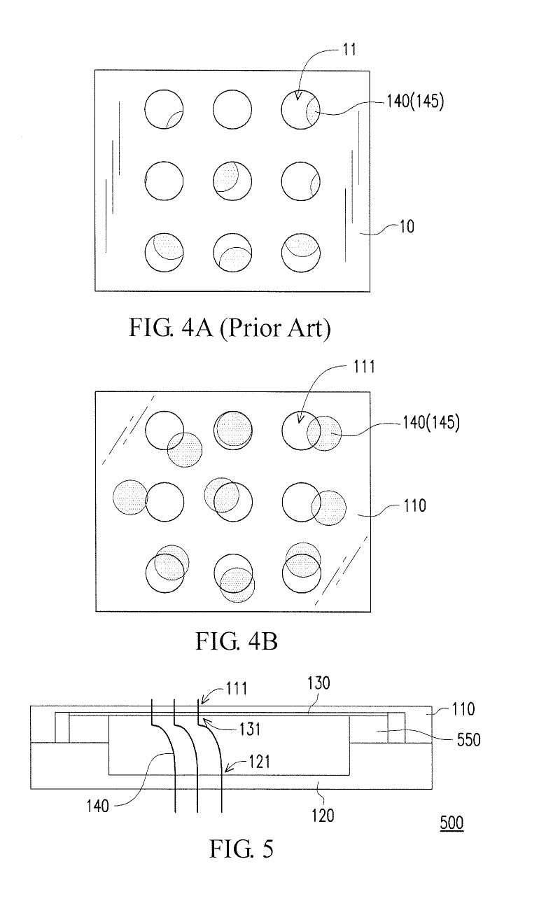

The process of inserting the tails 145 of the probes 140 into the upper through holes 111 of the upper guider plate 110 will be further illustrated in the following contents by reference to FIGS. 4A-4B.

FIG. 4A is a schematic view showing that the probes shown in FIG. 2C are about to be inserted through a conventional upper guider plate. FIG. 4B is a schematic view showing that the probes shown in FIG. 2C are about to be inserted through the upper guider plate shown in FIG. 1. In each of the embodiments shown in FIGS. 4A and 4B, the positioning through holes 131 are arranged correspondingly in position to the upper through holes 11, 111 of the upper guider plates 10, 110. However, in the embodiment shown in FIG. 4A, the conventional upper guider plate 10 is made of an opaque material. Therefore, under the condition of fine pitch, the positions of the tails 145 of the probes 140 can not be observed directly and precisely, but can only be observed through the upper through holes 11 of the upper guider plate 10 for rough determination. In such condition, if the tails 145 of the probes 140 are located out of the area of the upper through holes 11 of the upper guider plate 10, as shown in FIG. 4A, it is difficult to determine the positions of the tails 145 of the probes 140. At this time, if the upper guider plate 10 is directly capped onto the probes 140 to try to let the tails 145 of the probes 140 be inserted through the upper through holes 11, the probes 140 are liable to be damaged.

In contrast, the upper guider plate 110 in this embodiment as shown in FIG. 4B has the light transmittance of at least 75%. Therefore, while the tails 145 of the probes 140 are inserted through the upper through holes 111 of the upper guider plate 110, the precise positions of the tails 145 of the probes 140 can be observed directly. Even though the tails 145 of the probes 140 are located out of the area of the upper through holes 111 of the upper guider plate 110, the positions of the tails 145 of the probes 140 can be easily observed, such that all the tails 145 of the probes 140 can be easily adjusted to correspond in position to the upper through holes 111 before the upper guider plate 110 is capped onto the probes 140 to let the tails 145 of the probes 140 be inserted through the upper through holes 111 of the upper guider plate 110. In this way, the probes 140 are less possibly damaged in the assembling process of the probe head or after the upper guider plate 110 is installed and the probe head is completely assembled, and the efficiency of assembling the probe head 100 is also improved.

FIG. 5 is a lateral sectional view of a probe head according to another embodiment of the present invention. Referring to FIG. 5, the probe head 500 is similar to the probe head 100 as shown in FIG. 1, but has the difference as described hereinafter. The probe head 500 further includes a fastening member 550 which is shaped as a ring in this embodiment and disposed between the lower guider plate 120 and the positioning member 130. In this way, in the process that the probes 140 are inserted through the upper through holes 111 of the upper guider plate 110, the positioning through holes 131 of the positioning member 130 and the lower through holes 121 of the lower guider plate 120, the fastening member 550 can support and fasten the positioning member 130 in good position, so that the probes are conveniently installed. It should be mentioned that the upper guider plate 110 and the positioning member 130 are arranged in contact with each other in FIG. 5, but the upper guider plate 110 and the positioning member 130 of the present invention are not limited to be arranged in contact with each other.

Besides, the positioning member 130 and the upper guider plate 110 in this embodiment also have the light transmittance of at least 75%, and are made of the material having the Moh's hardness of at least 5. Therefore, the precise positions of the tails 145 of the probes 140 can be observed directly, so that the tails 145 of the probes 140 are easily inserted through the positioning through holes 131 of the positioning member 130 and the upper through holes 111 of the upper guider plate 110, the probes 140 are less possibly damaged, and the efficiency of assembling the probe head 500 is improved. Therefore, the effects and advantages of the probe head 500 are similar to that of the probe head 100, which will not be repeatedly mentioned hereunder.

In conclusion, the probe head provided in the embodiments of the present invention has the positioning member and the upper guider plate, which have the light transmittance of at least 75% and are made of the material having the Moh's hardness of at least 5. Therefore, in the assembling process of the probe head under the condition of conforming to the requirement of fine pitch, the lower through holes of the lower guider plate can be observed directly, thereby facilitating the installation of the probes. When the upper guider plate is aligned with the probes, the precise positions of the tails of the probes under the upper guider plate can be observed directly, so that the tails of the probes are easily inserted through the upper through holes of the upper guider plate. In this way, the probes are less possibly damaged in the installation process, and the efficiency of assembling the probe head can be improved. It should be mentioned that the lower guider plate in the present invention may, but not limited to, be made of a material having a light transmittance of at least 75% and a Mohs hardness of at least 5.

The invention has been described in the aforesaid embodiments, but the aforesaid embodiments are not intended to limit the scope of the invention. The invention may be able to be varied or modified by one skilled in the art, and such variations and modifications may not to be regarded as a departure from the spirit and scope of the invention. So the scope the invention intended to protect should be determined according to the following claims.

What is claimed is:

1. A probe head for a vertical probe card, the probe head comprising:
an upper guider plate having a plurality of upper through holes;
a lower guider plate located by one side of the upper guider plate and having a plurality of lower through holes; and
a plurality of probes, each of which is positioned through one of the upper through holes of the upper guider plate and one of the lower through holes of the lower guider plate;
wherein the upper guider plate has a light transmittance of at least 75%, and is made of a material having a Moh's hardness of at least 5;
wherein a pitch of at most 400 micrometers is provided between two adjacent said upper through holes of the upper guider plate.

2. The probe head as claimed in claim 1, wherein the upper guider plate has a thickness of at most 800 micrometers.

3. The probe head as claimed in claim 1, wherein the upper guider plate has a thickness ranging from 200 micrometers to 800 micrometers.

4. The probe head as claimed in claim 1, wherein each of the probes is a vertical buckling probe.

5. The probe head as claimed in claim 4, wherein each of the probes is provided in order with a pinpoint, a body and a tail; the tail has a circular cross section; the body has an elliptic or rectangular cross section, and an elastic portion forming a buckling structure.

6. The probe head as claimed in claim 1, wherein the pitch provided between two adjacent said upper through holes of the upper guider plate ranges from 40 micrometers to 400 micrometers.

7. The probe head as claimed in claim 1, wherein the upper guider plate is made of a glass substrate or a sapphire substrate.

8. The probe head as claimed in claim 1, further comprising at least one positioning member, which is disposed between the upper guider plate and the lower guider plate, has a light transmittance of at least 75%, and is made of a material having a Moh's hardness of at least 5.

9. The probe head as claimed in claim 8, wherein the positioning member has a plurality of positioning through holes corresponding in position to the upper through holes of the upper guider plate.

10. The probe head as claimed in claim 8, wherein the positioning member is made of a glass substrate or a sapphire substrate.

11. The probe head as claimed in claim 8, further comprising a fastening member disposed between the lower guider plate and the positioning member.

12. An upper guider plate for a probe head of a vertical probe card, the upper guider plate having a plurality of upper through holes, and being characterized in that:
the upper guider plate has a light transmittance of at least 75%, and is made of a material having a Moh's hardness of at least 5; a pitch of at most 400 micrometers is provided between two adjacent said upper through holes of the upper guider plate.

13. The upper guider plate as claimed in claim 12, having a thickness of at most 800 micrometers.

14. The upper guider plate as claimed in claim 12, having a thickness ranging from 200 micrometers to 800 micrometers.

15. The upper guider plate as claimed in claim 12, wherein the pitch provided between two adjacent said upper through holes of the upper guider plate ranges from 40 micrometers to 400 micrometers.

16. The upper guider plate as claimed in claim 12, being made of a glass substrate or a sapphire substrate.
